(19) United States
(12) Patent Application Publication
(10) Pub. No.: US 2001/0023957 A1
(43) Pub. Date: Sep. 27, 2001

(54) Trench-gate semiconductor devices

(75) Inventor: Andrew M. Warwick, Stockport (GB)

Correspondence Address: Corporate Patent Counsel, U.S. Philips Corporation, 580 White Plains Road, Tarrytown, NY, 10591, US

(73) Assignee: PHILIPS CORPORATION

(21) Appl. No.: 09/808,277

(22) Filed: Mar. 14, 2001

(30) Foreign Application Priority Data
Mar. 15, 2000 (GB) 0006092.1

(51) Int. Cl. H01L 29/76

(52) U.S. Cl. 257/301

(57) ABSTRACT

A trench-gate semiconductor device, for example a MOSFET or an IGBT, has a network of connected trenches (20) containing gate material (21) in a semiconductor body (10) in an active transistor cell area 100 with an n-type source region (13A) and an underlying channel accommodating p-type region (15A) in each cell. A source electrode (51) contacts the source regions (13A). Trenches (20) containing gate material (21) extend from the network of connected trenches in the area 100 to an inactive area (200) having a gate electrode contact area (201) where a gate electrode (53) contacts the gate material (21) on the whole area of the trenches (20) adjacent the semiconductor body surface (10a) and where the gate electrode (53) also contacts the semiconductor body surface (10a) adjacent the trenches (20). The semiconductor body surface (10a) contacted by the gate electrode (53) has n-type surface regions (13B) and underlying p-type regions (15B) to provide a voltage establishing diode between the gate electrode (53) and a drain electrode (52) of the device. In a modified device (FIGS. 6 and 7) at least some of otherwise isolated cells in the inactive area are instead linking cells (60) across the inactive and active areas. The linking cells, by means of continuous underlying p-type regions (15B, 15A) provide voltage protection diodes between the gate electrode (53) and the source electrode (51).

This invention relates to trench-gate semiconductor devices, for example an insulated-gate field-effect power transistor (commonly termed a “MOSFET”) or an insulated-gate bipolar transistor (commonly termed an “IGBT”). The invention also relates to methods of manufacturing such semiconductor devices.

Trench-gate semiconductor devices are known comprising a semiconductor body having an active cell area wherein trenches containing gate material extend into the semiconductor body from a surface thereof, wherein adjacent to each trench-gate there is a source region at said semiconductor body surface separated from a drain region by a channel-accommodating body region, and wherein a source electrode contacts the source regions on said semiconductor body surface. In the case of an insulated-gate device, such as a MOSFET or an IGBT, an insulating layer is provided in the trenches between the gate material in the trenches and the semiconductor body adjacent the trenches.

Trench-gate semiconductor devices are known having source and drain regions of a first conductivity type separated by a channel-accommodating body region of the opposite second conductivity type. Trench-gate semiconductor devices are also known in which the channel-accommodating body region is of the same, first conductivity type as the source and drain regions. In this case, the conductive channel is formed by charge-carrier accumulation by means of the trench-gate.

Trench-gate semiconductor devices of the known type described in the penultimate paragraph are disclosed, for example, in U.S. Pat. No. 5,795,792 (Nishihara). The background art discussion in this document indicates that chip size reduction and performance improvement requires reduction of trench widths, but that if trench width is reduced too much it can be difficult to directly form a contact with the gate material buried in the trench. It is therefore a generally practised approach to lead out the gate material from inside the trench to the main surface of the semiconductor substrate for contact with an electrode on that surface. Nishihara is concerned with insulated-gate devices where the gate insulating layer is a silicon oxide film, and there is a discussion of the further problem that conventional processing results in a thinning of this silicon oxide film just at the upper end corner portion of the trench where the gate material is led out from the trench to the main surface and that this thinning can greatly reduce the breakdown voltage of the silicon oxide film. The inventive disclosure of Nishihara concerns methods for increasing the silicon oxide thickness at this corner portion of the trench.

It is an aim of the present invention to provide a trench-gate semiconductor device with improved means for forming an electrode contact with the gate material. In the case of insulated-gate such devices, it is a further aim of the present invention to overcome the above-described problem of reduced insulating layer breakdown voltage which occurs where gate material is led out from the trench to the main semiconductor surface.

According to a first aspect of the present invention there is provided a trench-gate semiconductor device, comprising:

an active cell area having a network of connected trenches with a said source region in each cell, wherein the trenches contain gate material and extend from the network of connected trenches beyond the active cell area to an inactive area where said source regions are not present; and within said inactive area there is a gate electrode contact area where a gate electrode contacts the gate material on the whole area of the trenches adjacent the semiconductor body surface and where the gate electrode also contacts the semiconductor body surface adjacent the trenches.

Having trenches extending to an inactive area where a gate electrode contacts the gate material on the whole area of the trenches provides improved means for contact with the gate material applicable to devices having small trench widths.

U.S. Pat. No. 5,795,792 (Nishihara) discussed above discloses a device with separate stripe-shaped trenches extending into an inactive area where gate material is led out at the end of each trench over the top corner of a gate insulating layer to the semiconductor main surface. Devices having an active cell area with a network of connected trenches are known per se, for example in U.S. Pat. No. 5,648,670 (Blanchard), but where gate material is led out of the trench network at the periphery of the active cell area again over the top corner of a gate insulating layer to the semiconductor main surface.

In a semiconductor device according to the present invention, the semiconductor body surface contacted by the gate electrode may have first regions at that surface of one conductivity type, and said first regions may have underlying second regions of opposite conductivity type. The source regions in the active cell area and said first regions in the inactive area may be of a same first conductivity type, the channel-accommodating body regions in the active cell area and said second regions in the inactive area being of a same second conductivity type opposite to the first conductivity type, and a common layer of the first conductivity type providing the drain regions in the active cell area and underlying the second regions in the inactive area.

In a semiconductor device having the features defined in the preceding paragraph, it is possible to provide linking cells in the semiconductor body across the inactive and active areas providing voltage protection diodes between the gate electrode and the source electrode. The configuration of semiconductor regions within these linking cells and possible arrangements of these linking cells within the inactive area are fully set out in claims 5 and 6.

The trench-gate semiconductor device according to the present invention may be an insulated-gate device, wherein in the active cell area an insulating layer is provided in the trenches between the gate material in the trenches and the semiconductory body adjacent the trenches. This gate insulating layer does not have a top corner portion at the periphery of the active cell area over which the gate material is led out for contact with an electrode. Instead, the gate material is contacted by the gate electrode on the whole area of the trenches where they extend beyond the active cell area to the inactive area. The prior art problem of reduced insulating layer breakdown voltage at the mentioned top corner portion is therefore entirely avoided.

Further optional preferred features of the semiconductor device in accordance with the invention are set out in claims 4, 7, and 9.

According to a second aspect of the present invention there is provided a method of manufacturing a trench-gate semiconductor device, including the steps of:

(a) providing the semiconductor body with a first layer of a first conductivity type suitable for the drain regions and a second layer of a second conductivity type, opposite to the first conductivity type, suitable for the channel-accommodating body regions, the second layer overlying the first layer and extending to the surface of the semiconductor body;

(b) forming a network of connected trenches containing gate material in the active cell area where a said source region will be present in each cell, and at the same time forming trenches containing gate material extending from the network of connected trenches beyond the active cell area to an inactive area where the source regions will not be present in the device, the trenches extending past the second layer and into an underlying portion of the first layer in both the active and inactive areas, and planarising the top surface of the gate material level with the surface of the semiconductor body in both the active and inactive areas;

(c) forming surface regions of the first conductivity type extending into said second layer at the same time in both the active and inactive areas, the source regions being provided by said surface regions of first conductivity type in the active area;

(d) providing a patterned insulating layer on the semiconductor body, the insulating layer providing an insulating overlayer on the trench-gates in the active area, the insulating layer having windows where the source electrode will contact the source regions in the active area, and the insulating layer having a window providing a gate electrode contact area within the inactive area; and

(e) providing a conductive material to form the source electrode contacting the source regions at said insulating layer windows in the active area, and at the same time providing the conductive material to form a gate electrode, the gate electrode contacting the gate material on the whole area of the trenches adjacent the semiconductor body surface at said insulating layer window in the inactive area, and the gate electrode also contacting said surface regions of the first conductivity type at the semiconductor body surface adjacent the trenches at said insulating layer window in the inactive area.

The semiconductor device produced by the method just defined has the same features with the same advantages as the semiconductor device defined in accordance with the first aspect of the invention.

The method of the invention may produce the linking cells mentioned above in relation to claims 5 and 6 which provide voltage protection diodes between the gate electrode and the source electrode. An additional advantage of the method in this case is that, as set out in claims 11 and 12, the same steps which provide the active transistor cells and which provide contact to the trench-gates can also produce these linking cells.

The method according to the invention may further include the step of providing an insulating layer in the trenches in the active cell area between the gate material in the trenches and the semiconductor body adjacent the trenches, thus making an insulated-gate device. Methods for making prior art insulated-gate devices in which gate material is led out over top corners of individual trenches, or over the top corner of connected trenches, for contact with an electrode require a photolithographic mask stage to enable this led out gate material to be retained when the remainder of deposited gate material is made level with the semiconductor main surface to provide the trench gates. An advantage of the method according to the invention when making insulated-gate devices is that, as specified in step (b), the top surface of the gate material is planarised level with the surface of the semiconductor body in both the active and inactive areas so that there is no need for the just-mentioned prior art photolithographic mask stage.

Embodiments of the invention will now be described, by way of example, with reference to the accompanying diagrammatic drawings, in which:

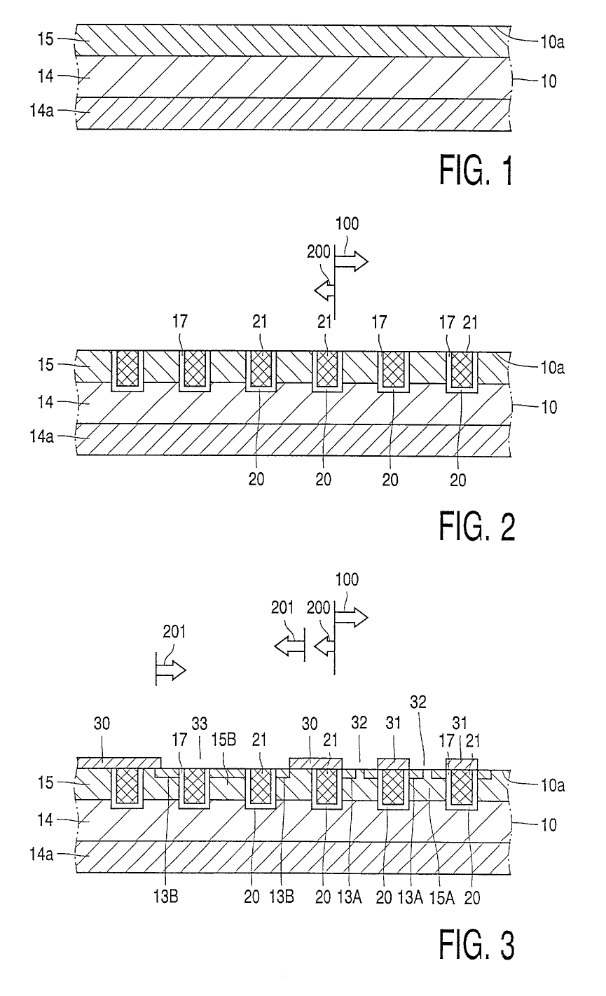

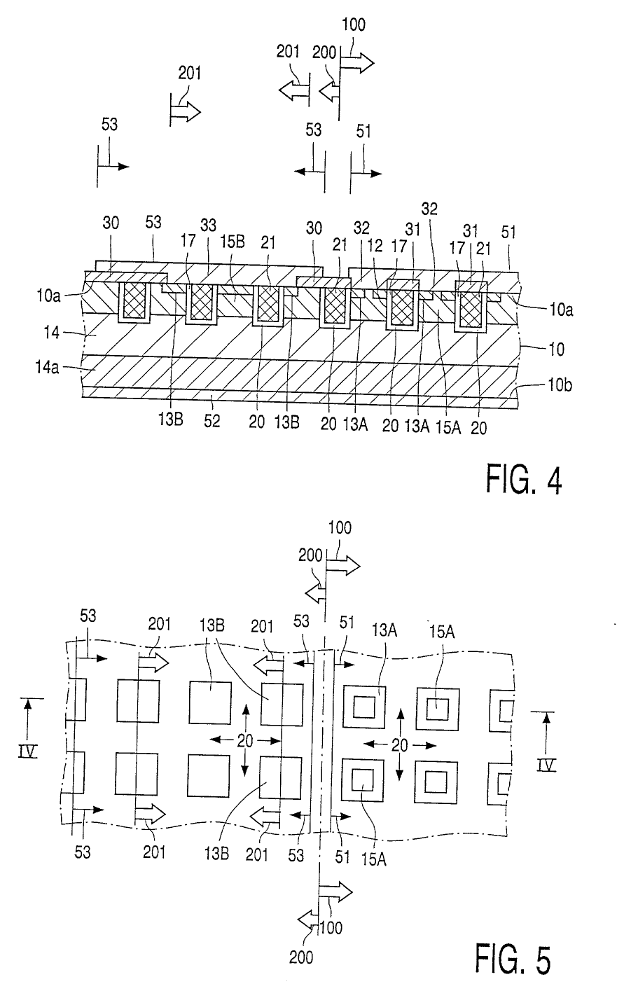

FIGS. 1 to 4 are a cross-sectional view of part of a semiconductor body at successive stages in the manufacture of a trench-gate semiconductor device by an example of a method in accordance with the present invention, FIG. 4 showing an example of part of a trench-gate semiconductor device in accordance with the present invention;

FIG. 5 is a plan view of the device shown in FIG. 4, the line IV-IV indicating where the cross-section of FIG. 4 is taken;

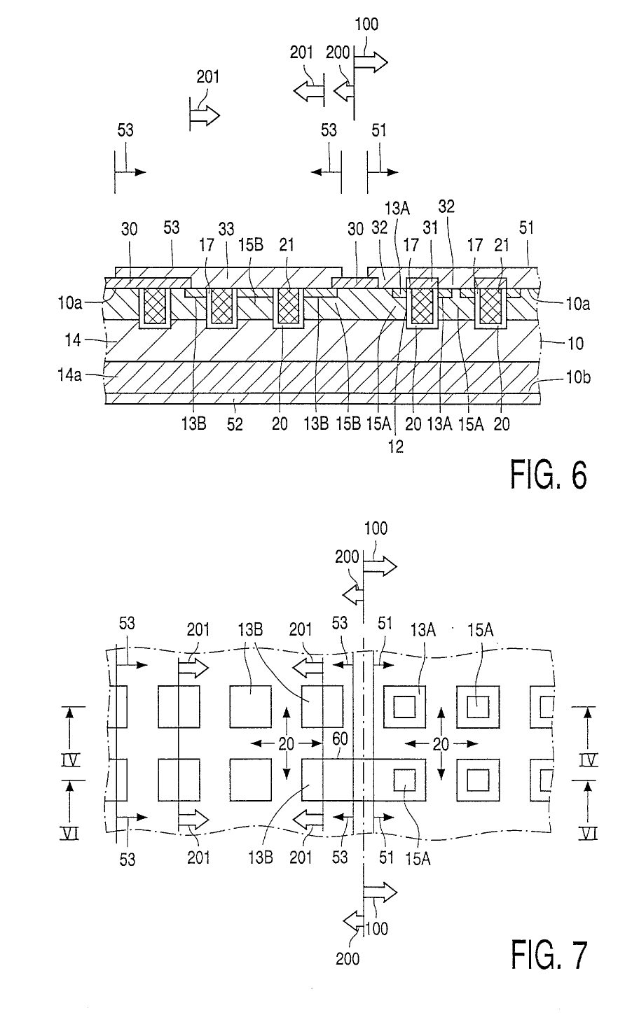

FIG. 6 is a cross-sectional view of a semiconductor device modified with respect to the device shown in FIG. 4 and also in accordance with the present invention;

FIG. 7 is a plan view of the device shown in FIG. 6, the line VI-VI indicating where the cross-section of FIG. 6 is taken and the line IV-IV indicating where a cross-section of this modified device is the same as that shown in FIG. 4;

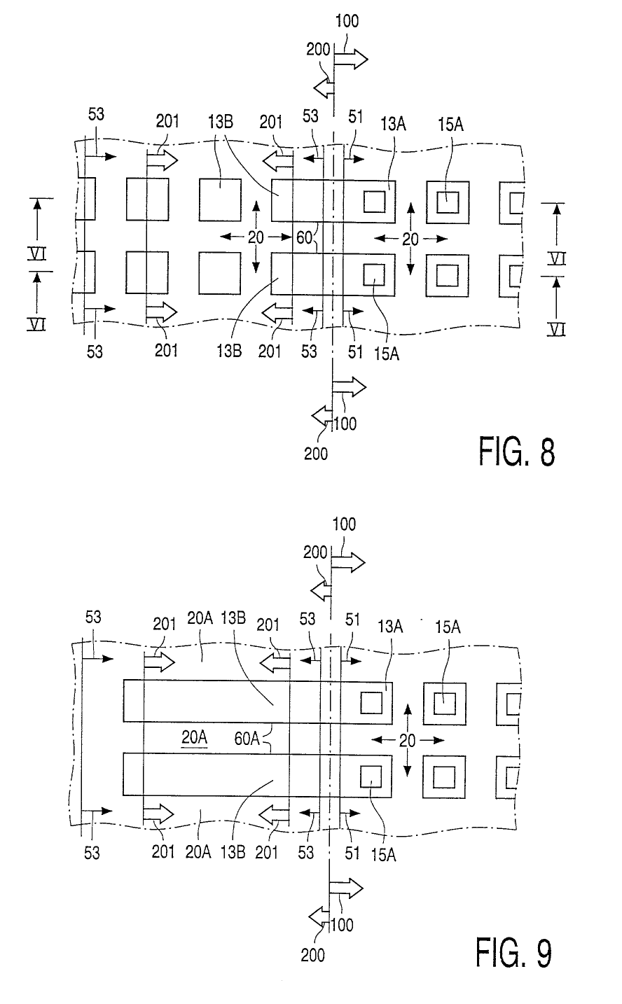

FIG. 8 is a plan view of a further modified semiconductor device also in accordance with the invention, the two lines VI-VI indicating that cross-sections along both these lines are the same as that shown in FIG. 6; and

FIG. 9 is a plan view of a further modified semiconductor device also in accordance with the invention.

It should be noted that all the Figures are diagrammatic and not drawn to scale. Relative dimensions and proportions of parts of the drawings have been shown exaggerated or reduced in size, for the sake of clarity and convenience in the drawings. The same reference signs are generally used to refer to corresponding or similar features in different stages of manufacture and in modified and different embodiments.

FIGS. 4 and 5 illustrate an exemplary embodiment of a trench-gate power semiconductor device having an active transistor cell area 100 and an inactive area 200. A semiconductor body 10 has a network of connected trenches 20 containing gate material 21 extending into the body 10 from a top major surface 10a thereof.

In the active cell area 100 the trenches 20 surround square shaped transistor cells and the gate material 21 provides a trench-gate for each cell. Adjacent to the trench-gate in each transistor cell there is an annular source region 13A at the semiconductor body surface 10a separated from a drain region 14 by a channel-accommodating body region 15A. The source and drain regions 13A and 14 are respectively of a first conductivity type (n-type in this example) and the channel-accommodating body regions 15A are of the opposite second conductivity type (i.e. p-type in this example). The trench-gates 21 extend through the regions 13A and 15A into an underlying portion of the drain region 14. An insulating layer 17 is provided in the trenches 20 between the gate material 21 in the trenches and the semiconductor body adjacent the trenches. The application of a voltage signal to the gates 21 in the on-state of the device serves in known manner for inducing a conduction channel 12 in the region 15A in each transistor cell and for controlling current flow in this conduction channel 12 between the source and drain regions 13A and 14 in each transistor cell.

A patterned insulating layer 30 is provided on the semiconductor body 10. In the active cell area 100 the insulating layer 30 provides an insulating overlayer 31 on the trench-gates 21 and the insulating layer 30 has windows 32 where a source electrode 51 contacts the source regions 13A and the body regions 15A at the top major surface 10a of the device body. By way of example, FIGS. 4 and 5 show a vertical device structure in which the region 14 may be a drain-drift region formed by an epitaxial layer of high resistivity (low doping) on a substrate region 14a of high conductivity. This substrate region 14a may be of the same conductivity type (n-type in this example) as the region 14 to provide a vertical MOSFET, or it may be of opposite conductivity type (p-type in this example) to provide a vertical IGBT. The substrate region 14a is contacted at the bottom major surface 10b of the device body by an electrode 52, called the drain electrode in the case of a MOSFET and called the anode electrode in the case of an IGBT.

Still referring to FIGS. 4 and 5, the network of connected trenches 20 containing gate material 21, and having an insulating layer 17 provided in the trenches, extends beyond the active cell area 100 to the inactive area 200 where the annular source regions 13A are not present. The insulating layer 30 extends to the inactive area, and a window 33 in the insulating layer 30 in the inactive area 200 provides a gate electrode contact area 201 where a gate electrode 53 contacts the gate material 21 on the whole area of the trenches 20 adjacent the surface 10a of the semiconductor body and where the gate electrode 53 also contacts the semiconductor body surface 10a at square areas surrounded by the trenches 20. The semiconductor body surface 10a contacted by the gate electrode 53 has first regions 13B of the first conductivity type, the first regions 13B having underlying second regions 15B of the second conductivity type. The layer 14 of the first conductivity type is a common layer which underlies the second regions 15B in the inactive area 200 as well as providing the drain regions in the active cell area 100. The regions 13B of first conductivity type and the underlying regions 15B of the second conductivity type provide a reverse-biased diode between the gate electrode 53 and the drain/anode electrode 52 of the device. Although the regions 15B are not directly connected to the regions 15A, they are both connected to the common underlying region 14. The reverse-biased diode between the regions 13B and 15B therefore enables the necessary voltage to be established between the gate electrode 53 and the drain/anode electrode 52, and also between the gate electrode 53 and the source electrode 51, in the on-state of the device.

Gate and source bond pads for the device may be provided at respective holes in a top passivation layer (not shown) over the gate electrode 53 and source electrode 51. The gate bond pad may be conveniently provided by the gate electrode 53 within the gate contact area 201.

FIG. 5 shows the network of connected trenches 20 surrounding square shaped transistor cells in the active area 100 and similarly square shaped regions in the inactive area 200. Different known transistor cell geometries may be used. Thus for example the cells may have a hexagonal or an elongate stripe geometry, in which case a cross section through the cells would be the same as shown in FIG. 4. FIGS. 4 and 5 show only a few transistor cells, but typically the device comprises many hundreds of these parallel cells between the electrodes 51 and 52.

Successive stages in the manufacture of the device of FIGS. 4 and 5 will now be described with reference to FIGS. 1 to 4.

Referring to FIG. 1, a semiconductor body 10 of monocrystalline silicon material is first provided having a substrate region 14a of high conductivity on which there is formed an epitaxial high resistivity (low-doped) n-type first layer 14 suitable for the drain drift region, and an epitaxial p-type second layer 15 on top of the first layer 14 and extending to a top major surface 10a of the semiconductor body 10. The layer 15 is suitable for the channel-accommodating body regions 15A and the underlying second regions 15B. The layer 15 may alternatively be formed by introducing dopants into the layer 14, for example by implantation of suitable dopant ions followed by heating to diffuse the respective dopant to the desired depth for the layer 15.

Referring to FIG. 2, a network of connected trenches 20 containing gate material 21 is formed in an active cell area 100 where a source region will be present in each cell, and at the same time trenches 20 containing gate material 21 are formed extending from the network of connected trenches beyond the active cell area 100 to an inactive area 200 where source regions will not be present in the device. The trenches 20 extend past the second layer 15 and into an underlying portion of the first layer 14 in both the active area 100 and the inactive area 200. To form the trenches, a mask (not shown) is first provided at the surface 10a of the semiconductor body 10. This mask can be formed by depositing silicon dioxide material and subsequently opening windows using known photolithographic and etching techniques. A silicon-etching treatment is then carried out in known manner to etch the trenches 20 into the silicon body 10 at the windows in the mask. The layout pattern of the trenches 20 is a grid surrounding isolated square areas. The width of the etched trenches 20 may be, for example, in the range of 0.5 μm to 1.0 μm. The silicon body 10 and the oxide mask are then subjected to an oxidation treatment to grow a thin silicon dioxide layer on the exposed faces of the trenches 20 which provides a gate insulating layer 17 in the trenches. Doped polycrystalline silicon gate material 21 is then deposited in the trenches 20 in the active area 100 and in the inactive area 200 and on the top surface of the oxide mask. The deposited polycrystalline silicon gate material 21 is then etched back so that its top surface is planarised level with the surface 10a of the silicon body 10 in both the active area 100 and the inactive area 200. The oxide mask is then removed from the surface 10a of the silicon body 10.

Referring to FIG. 3, n-type surface regions 13A and 13B extending into the layer 15 are formed at the same time in the active area 100 and in the inactive area 200. For this purpose a mask (not shown) is formed by depositing a continuous layer of resist material on the silicon body and then forming windows in this layer in a standard manner using photolithography and etching. These windows have an annular shape in the square transistor cell areas surrounded by the trenches 20 in the active region 100, and these windows extend across all or part of the square areas surrounded by the trenches 20 in that part of the inactive area 200 where a gate electrode contact area 201 will later be formed. An implantation of donor ions (for example of phosphorous or arsenic) is then carried out to form implanted regions 13A and 13B in the layer 15 at the windows in the resist mask, followed by a heating treatment for annealing and diffusing these donor implant regions. In the active area 100, the n-type regions 13A form transistor cell source regions and the underlying layer 15 provides channel-accommodating body regions 15A. In the inactive area 200, the n-type regions 13B form first regions and the underlying p-type layer 15 provides second regions 15B for a diode.

Referring further to FIG. 3, after forming the n-type surface regions 13A and 13B as described above, a patterned insulating layer 30, which may suitably be of silicon dioxide, is provided on the surface 10a of the semiconductor body 10. This insulating layer provides an insulating overlayer 31 on the trench-gates 21 in the active area 100. This insulating layer has windows 32 where a source electrode will contact the source regions 13A and the body regions 15A in the active area 100, and this insulating layer has a window 33 providing a gate electrode contact area 201 within the inactive area 200. The windows 32 and 33 may be provided by dry etching after depositing a continuous layer of silicon dioxide.

Referring to FIGS. 4 and 5, conductive electrode material (for example aluminium) is deposited to form a source electrode 51 and at the same time to form a gate electrode 53. The source electrode 51 contacts the exposed silicon surface 10a of source regions 13A and the regions 15A at the insulating layer windows 32 in the active area 100. The gate electrode 53 contacts the gate material 21 on the whole area of the trenches 20 adjacent the semiconductor body surface 10a at the insulating layer window 33 in the inactive area 200, and the gate electrode 53 also contacts the n-type surface regions 13B at the semiconductor body surface 10a adjacent the trenches at the insulating layer window 33 in the inactive area. The lateral extent of the source electrode 51 and the gate electrode 53 is determined in known manner by photolithographic definition and etching of the deposited electrode material.

Modifications and variations of the device shown in FIGS. 4 and 5, and the method of FIGS. 1 to 5, within the scope of the present invention will now be discussed.

Referring to FIGS. 6 and 7, a semiconductor device is shown which is modified with respect to the device shown in FIGS. 4 and 5. In the device of FIGS. 4 and 5, all the n-type first regions 13B and underlying p-type second regions 15B in the inactive area 200 are provided as isolated cells surrounded by the trenches 20. FIGS. 6 and 7 show that in one of the rows of cells, along the line VI-VI in FIG. 7, an isolated cell in the inactive area 200 which is nearest to the active area 100 is instead a linking cell 60 across the inactive and active areas. The linking cell 60 has a first region 13B contacted by the gate electrode 53, a source region 13A contacted by the source electrode 51, and an underlying second region 15B continuous withd a channel-accommodating body region 15A which extends to the semiconductor body surface where it is contacted by the source electrode 51. The linking cell 60 provides voltage a protection diode, at the junction between the n-type region 13B and the p-type region 15B, 15A, between the gate electrode 53 and the source electrode 51. The diode between the regions 13B and 15B, 15A in the linking cell 60 has an appropriate voltage between the gate electrode 53 and the source electrode 51 when the device is in its on-state but if this voltage reaches a high limit due to electrostatic discharge (ESD) then this diode has zener breakdown.

The line IV-IV shown in FIG. 7 indicates that the other row of cells across the inactive and active areas 200,100 does not have a linking cell 60 and thus has the same cross-section as shown in FIG. 4. The device which is modified as shown in FIGS. 6 and 7 may have, for example, alternate rows of cells provided with a linking cell 60. The same method steps which provide the active transistor cells and which provide contact to the trench gates, as described in relation to FIGS. 1 to 5, can also produce the linking cells 60. All that is required is a suitable modification of the silicon dioxide mask used to form the trenches 20 as described above with reference to FIG. 2 and of the resist mask used to form the regions 13A and 13B as described above with reference to FIG. 3.

FIG. 8 is a plan view of a further modified semiconductor device, the two lines VI-VI indicating that cross-sections along both these lines are the same as that shown in FIG. 6. In this device, all the isolated cells in the inactive area 200 which are nearest to the active area 100 as shown in FIG. 5 are instead a linking cell 60 which is configured and produced as has been described above in relation to FIGS. 6 and 7. The FIG. 8 arrangement will provide more diode conduction area to accommodate current for electrostatic discharge protection between the gate and source electrodes.

FIG. 9 is a plan view of a further modified semiconductor device. In this device, the trenches 20A which extend from the network of connected trenches 20 in the active cell area 100 are stripe shaped trenches 20A which each extend completely across the gate electrode contact area 201. Linking cells 60A are provided across the inactive 200 and active 100 areas between the stripe shaped trenches 20A. In the same manner as for the linking cells 60 described with reference to FIGS. 6 and 7, each linking cell 60A has a first region 13B contacted by the gate electrode 53, a source region 13A contacted by the source electrode 51, and an underlying second region 15B continuous with a channel-accommodating body region 15A which extends to the semiconductor body surface where it is contacted by the source electrode 51. The linking cells 60A provide voltage protection diodes between the gate electrode 53 and the source electrode 51. An advantage of the FIG. 9 arrangement is as follows. In the devices described with reference to FIGS. 4 to 8, there are cells in the inactive area 200 having n-type first regions 13B and underlying p-type second regions 15B, which cells are isolated by the trenches 20. Together with the underlying n-type region 14, these cells form unshorted parasitic bipolar transistors which might turn on. In the arrangement of FIG. 9 having only linking cells 60A, these isolated cells are not present in the inactive area and such parasitic bipolar transistors are to an extent shorted by the regions 15B being continuous with the regions 15A in the linking cells 60A and contacted by the source electrode 51. There is therefore less risk of these parasitic bipolar transistors turning on.

Further possible modifications are as follows.

A polycrystalline silicon semiconductor layer may be provided on the silicon dioxide insulating layer 30 outside the gate electrode contact area 201 away from the active area 100 and connected to a strap extension of the gate electrode 53 over the insulating layer 30. This semiconductor layer may be patterned in separate portions and each portion may be connected to a strap from the gate electrode 53. The semiconductor layer will be formed in a required pattern by depositing polycrystalline silicon and then using photolithographic masking and etching. Two uses for the patterned polycrystalline silicon semiconductor layer are as follows. One use is that this layer may provide one or more peripheral polycrystalline silicon field plates for the device. Another use is that semiconductor diodes may be formed in this layer. These diodes may be connected by a wire or the like to form protection diodes for the device between the gate electrode 53 and either the drain electrode 52 or the source electrode 51.

Usually the conductive trench-gates 21 are formed of doped polycrystalline silicon as described above. However, other known gate technologies may be used in particular devices. Thus, for example, additional materials may be used for the gate, such as a thin metal layer that forms a silicide with the polycrystalline silicon material. Alternatively, the whole of the trench-gates 21 may be of a metal instead of polycrystalline silicon. FIGS. 1 to 9 illustrate the preferred situation of an insulated gate structure, in which each conductive gate 21 is capacitively coupled to the channel-accommodating body region 15A by a dielectric layer 17. However, so-called Schottky gate technologies may alternatively be used. In this case, a gate dielectric layer 17 is absent and the conductive gates 21 are of a metal that forms a Schottky barrier with the low-doped channel-accommodating portions of the body region 15. The Schottky gates 21 are capacitively coupled to the channel-accommodating regions 15A by the depletion layer present at the Schottky barrier.

FIGS. 4 to 9 illustrate devices having a p-type body region 15A of a uniform depth in each transistor cell, without any deeper, more highly doped (p+) region such as is often used to improve device ruggedness. Some of the transistor cells (not shown) of the devices of FIGS. 4 to 9 may comprise a deeper, more highly doped (p+) region instead of the channel-accommodating region 15A. These deeper, more highly doped (p+) regions may be implanted through windows of an appropriate mask, for example before or after the FIG. 2 stage. It is also possible to implant a deeper, more highly doped (p+) localised region within an active cell having a channel-accommodating region 15A, but the cell geometry is less compact in this case.

The particular examples described above are n-channel devices, in which the regions 13A, 13B and 14 are of n-type conductivity, the layer 15 is of p-type, and an electron inversion channel 12 is induced in the regions 15A by the gates 21 in the active area. By using opposite conductivity type dopants, a p-channel device can be manufactured in accordance with the invention. In this case, the regions 13A, 13B and 14 are of p-type conductivity, the layer 15 is of n-type, and a hole inversion channel 12 is induced in the regions 15A by the gates 21.

Similar processing steps may even be used to manufacture an accumulation-mode device in accordance with the invention. Such a device of the p-channel type has p-type source and drain regions 13A and 14a, and p-type channel-accommodating regions 15A. It may also have an n-type deep localised region within each cell. Doped polycrystalline silicon may be used for the gates 21. In operation, a hole accumulation channel 12 is induced in the regions 15A by the gates 21 in the on-state. The low-doped p-type regions 15A may be wholly depleted in the off-state, by depletion layers from the insulated gates 21 and from the deep n-type region. In this case an extra implant stage will be required so that the protection diode regions 13B are n-type.

A vertical discrete device has been illustrated with reference to FIGS. 1 to 9 having its second main electrode 52 contacting the region 14a at the back surface 10b of the body 10. However, an integrated device is also possible in accordance with the invention. In this case, the region 14a may be a doped buried layer between a device substrate and the epitaxial low-doped drain region 14. The buried layer region 14a may be contacted by an electrode 52 at the front major surface 10a, via a doped peripheral contact region which extends from the surface 10a to the depth of the buried layer.

1. A trench-gate semiconductor device, comprising:
a semiconductor-body having an active cell area wherein trenches containing gate material extend into the semiconductor body from a surface thereof, wherein adjacent to each trench-gate there is a source region at said semiconductor body surface separated from a drain region by a channel-accommodating body region, and wherein a source electrode contacts the source regions on said semiconductor body surface; characterised in that
the active cell area has a network of connected said trenches with a said source region in each said cell;
trenches containing gate material extend from the network of connected trenches beyond the active cell area to an inactive area where said source regions are not present; and
within said inactive area there is a gate electrode contact area where a gate electrode contacts the gate material on the whole area of the trenches adjacent the semiconductor body surface and where the gate electrode also contacts the semiconductor body surface adjacent the trenches.

2. A semiconductor device as claimed in claim 1, wherein the semiconductor body surface contacted by the gate electrode has first regions at that surface of one conductivity type, said first regions having underlying second regions of opposite conductivity type.

3. A semiconductor device as claimed in claim 2, wherein the source regions in the active cell area and said first regions in the inactive area are of a same first conductivity type, wherein the channel-accommodating body regions in the active cell area and said second regions in the inactive area are of a same second conductivity type opposite to the first conductivity type, and wherein a common layer of the first conductivity type provides the drain regions in the active cell area and underlies the second regions in the inactive area.

4. A semiconductor device as claimed in claim 3, wherein said first regions and said underlying second regions in the inactive area are provided as isolated cells surrounded by a further network of connected trenches which is an extension of the network of connected trenches in the active cell area.

5. A semiconductor device as claimed in claim 4, modified in that at least some of said isolated cells in the inactive area which are nearest to the active area are instead linking cells across the inactive and active areas, wherein each linking cell has a said first region contacted by the gate electrode, a source region contacted by the source electrode, and a said underlying second region continuous with a said channel-accommodating body region which extends to the semiconductor body surface where it is contacted by the source electrode, the linking cells providing voltage protection diodes between the gate electrode and the source electrode.

6. A semiconductor device as claimed in claim 3, wherein said trenches which extend from the network of connected trenches in the active cell area are stripe shaped trenches which each extend completely across the gate electrode contact area, wherein linking cells are provided across the inactive and active areas between the stripe shaped trenches, wherein each linking cell has a said first region contacted by the gate electrode, a source region contacted by the source electrode, and a said underlying second region continuous with a said channel-accommodating body region which extends to the semiconductor body surface where it is contacted by the source electrode, the linking cells providing voltage protection diodes between the gate electrode and the source electrode.

7. A semiconductor device as claimed in any one of claims 1 to 6, wherein a patterned insulating layer is provided on the semiconductor body, wherein in the active cell area the insulating layer provides an insulating overlayer on the trench-gates and the insulating layer has windows where the source electrode contacts the source regions, and wherein in the inactive area a window in the insulating layer provides the gate electrode contact area.

8. A semiconductor device as claimed in any preceding claim, wherein in the active cell area an insulating layer is provided in the trenches between the gate material in the trenches and the semiconductor body adjacent the trenches.

9. A semiconductor device as claimed in any preceding claim, wherein the gate electrode provides a gate bond pad within the gate electrode contact area.

10. A method of manufacturing a trench-gate semiconductor device, the device comprising:
a semiconductor body having an active cell area wherein trenches containing gate material extend into the semiconductor body from a surface thereof, wherein adjacent to each trench-gate there is a source region at said semiconductor body surface separated from a drain region by a channel-accommodating body region, and wherein a source electrode contacts the source regions on said semiconductor body surface; characterised in that the method includes the steps of:
(a) providing the semiconductor body with a first layer of a first conductivity type suitable for the drain regions and a second layer of a second conductivity type, opposite to the first conductivity type, suitable for the channel-accommodating body regions, the second layer overlying the first layer and extending to the surface of the semiconductor body;
(b) forming a network of connected trenches containing gate material in the active cell area where a said source region will be present in each cell, and at the same time forming trenches containing gate material extending from the network of connected trenches beyond the active cell area to an inactive area where the source regions will not be present in the device, the trenches extending past the second layer and into an underlying portion of the first layer in both the active and inactive areas, and planarising the top surface of the gate material level with the surface of the semiconductor body in both the active and inactive areas;
(c) forming surface regions of the first conductivity type extending into said second layer at the same time in both the active and inactive areas, the source regions being provided by said surface regions of first conductivity type in the active area;
(d) providing a patterned insulating layer on the semiconductor body, the insulating layer providing an insulating overlayer on the trench-gates in the active area, the insulating layer having windows where the source electrode will contact the source regions in the active area, and the insulating layer having a window providing a gate electrode contact area within the inactive area; and
(e) providing a conductive material to form the source electrode contacting the source regions at said insulating layer windows in the active area, and at the same time providing the conductive material to form a gate electrode, the gate electrode contacting the gate material on the whole area of the trenches adjacent the semiconductor body surface at said insulating layer window in the inactive area, and the gate electrode also contacting said surface regions of the first conductivity type at the semiconductor body surface adjacent the trenches at said insulating layer window in the inactive area.

11. A method as claimed in claim 10, wherein said extending trenches are formed in step (b) as a further network of connected trenches which is an extension of the network of connected trenches in the active cell area, wherein isolated cells surrounded by the further network of connected trenches are provided in the inactive area by the surface regions of the first conductivity type formed in step (c) and underlying regions of the second layer, with the modification that at least some of said isolated cells in the inactive area which are nearest to the active area are instead linking cells across the inactive and active areas, wherein after the provision of the insulating layer in step (d) and the provision of the source and gate electrodes in step (e) each linking cell has a said surface region of the first conductivity type contacted by the gate electrode, a source region contacted by the source electrode, and a region of said second layer underlying said surface region and continuous with a said channel-accommodating body region which extends to the semiconductor body surface where it is contacted by the source electrode, the linking cells providing voltage protection diodes between the gate electrode and the source electrode.

12. A method as claimed in claim 10, wherein said extending trenches are formed in step (b) as stripe shaped trenches which each will extend completely across the gate electrode contact area, wherein linking cells are provided across the inactive and active areas between the striped shaped trenches by the surface regions of the first conductivity type formed in step (c) and underlying regions of the second layer, wherein after the provision of the insulating layer in step (d) and the provision of the source and gate electrodes in step (e) each linking cell has a said surface region of the first conductivity type contacted by the gate electrode, a source region contacted by the source electrode, and a region of said second layer underlying said surface region and continuous with a said channel-accommodating body region which extends to the semiconductor body surface where it is contacted by the source electrode, the linking cells providing voltage protection diodes between the gate electrode and the source electrode.

13. A method as claimed in any one of claims 10 to 12, further including the step of providing an insulating layer in the trenches in the active area and in the inactive area between the gate material in the trenches and the semiconductor body adjacent the trenches.

14. A method as claimed in any one of claims 10 to 13, further including the step of providing a gate bond pad with the gate electrode within the gate electrode contact area.
